(19) United States
(12) Patent Application Publication
(10) Pub. No.: US 2024/0080975 A1
(43) Pub. Date: Mar. 7, 2024

(54) CIRCULAR MANUFACTURING OF TEXTILE-BASED SENSORS

(71) Applicant: Accenture Global Solutions Limited, Dublin (IE)

(72) Inventors: Irmandy Wicaksono, Boston, MA (US); Aditi Maheshwari, San Francisco, CA (US); Lavinia Andreea Danielescu, Seattle, WA (US)

(21) Appl. No.: 18/241,397

(22) Filed: Sep. 1, 2023

Related U.S. Application Data
(60) Provisional application No. 63/403,591, filed on Sep. 2, 2022.

(51) Int. Cl. H05K 1/03; D06C 7/04; D06M 11/74; D06M 15/03; D06M 15/643; D06M 15/693; D06M 23/10; H05K 3/32

(52) U.S. Cl. CPC H05K 1/038; D06C 7/04; D06M 11/74; D06M 15/03; D06M 15/643; D06M 15/693; D06M 23/10; H05K 3/32; D06M 2101/02; D10B 2401/16; D10B 2505/00; H05K 2201/10151; H05K 2203/1105

(57) ABSTRACT

A method of producing a textile sensor includes: obtaining an organic fabric; carbonizing the organic fabric by applying heat to the organic fabric in an inert environment to form a conductive fabric; and attaching one or more electrical terminals to the conductive fabric. The method includes coating the conductive fabric with a polymeric encapsulating material. The method includes, for each of the one or more electrical terminals, connecting a first end of a flexible conductor to the electrical terminal and connecting a second end of each flexible conductor to a wireless interface printed circuit board. The textile sensor comprises at least one of a pressure sensor, a proximity sensor, a touch sensor, a strain sensor, a wind sensor, a temperature sensor, a heating element, a triboelectric sensor, and an energy harvester.

### CROSS REFERENCE TO RELATED APPLICATIONS

This application claims the benefit of the U.S. Provisional Patent Application No. 63/403,591, filed Sep. 2, 2022, which is incorporated herein by reference in its entirety.

### FIELD

This specification generally relates to textile-based sensors and processes for manufacturing the sensors.

### BACKGROUND

Textile-based sensors are sensors that are made of and/or integrated into textiles and that are configured to detect or measure a physical or chemical property. The merging of electronic materials and textiles has triggered the proliferation of wearables and interactive surfaces in the ubiquitous computing era. This leads to electronic textile (“e-textile”) waste that is difficult to recycle and decompose.

### SUMMARY

This specification generally describes textile-based sensors and processes for manufacturing the sensors. Textile-based sensors, which can also be referred to as textile sensors or fabric sensors, described in this document are configured and manufactured in ways that enhance sustainability and decomposition of the textile sensors. For example, the textile sensors can include organic fabric such as organic waste fabric that has been derived from natural resources and previously used for other purposes. The organic fabric can be carbonized to increase electrical conductivity in order to implement the fabric as a sensor. The carbonized fabric can also be encapsulated to improve the durability, strength, and washability of the fabric. The carbonized (and optionally encapsulated) fabric can then be used to produce a textile sensor. Each step of the manufacturing process and the materials used to construct the textile sensor (e.g., degradable organic waste fabric and/or degradable encapsulation materials) can be selected to enhance the sustainability and decomposition of the textile sensor.

The described manufacturing processes and textile sensors functionalize organic fabric, e.g., cotton, silk, linen, and so on, into conductive, capacitive, triboelectric, and piezoresistive sensors through solution-based and carbonization processes. The organic fabrics can be coated with carbon-based conductive solution made from carbon powder mixed with solvent, carbonized in a high-temperature furnace with inert gas, or carbonized in another appropriate way in order to form a conductive fabric. The conductive fabric can then be encapsulated in a soft polymeric substrate including Ecoflex™, Polydimethylsiloxane (PDMS), natural rubber latex (NRL), and/or Chitosan to improve the fabric's durability and washability. Based on the textile structures, encapsulation techniques, and terminal connections, the functionalized fabrics can be configured as proximity, touch, strain, pressure, bend, and heat sensors, as well as heating elements and self-powered sensors and energy harvesters. An interface circuit, which can be wired or wireless, can connect to various functional fabric elements within a larger system. For example, a system can include an interface circuit connected to multiple sensors disposed on or in a health monitoring suit (e.g., for rehabilitation, telemedicine, or training), a uniform, a haptic-transfer fabric for telepresence, joint-sensing wearables for digital immersion and/or entertainment, other types of wearables, sails of sailboats (e.g., a sailcloth for aerodynamic sensing), and/or in fabrics for other purposes. Towards their end-of-life, the sensors can be decomposed, or carbonized back to carbon powder and recoated on waste fabrics to enable a sustainable and circular manufacturing process.

Advantages of the disclosed techniques include at least the following. The described solutions provide low-cost and industrial processes to recycle and repurpose waste fabrics into various textile sensors through material choices (organic waste fabrics and flexible polymers), disassembly techniques (modular circuit and integration), and manufacturing approaches (dip-coating and carbonization). Encapsulation techniques can improve the sensitivity, durability, and washability of the textile sensors and approaches to measure various parameters. Measured parameters can include, for example, joint kinematics through integration of the textile sensors into smart suits, and wind speed and direction through integration of the textile sensors into sailcloth. The described solutions also promote environmental sustainability by using waste and discarded fabrics to create textile sensors which can be decomposed in unencapsulated form or when encapsulated within degradable (e.g., chemically degradable and/or biodegradable) polymers. Additionally, through inert gas carbonization, the sensors are turned back into conductive powder and recoated to create other sensors.

In general, one innovative aspect of the subject matter described in this specification can be embodied in a method of producing a textile sensor, including: obtaining an organic fabric; carbonizing the organic fabric by applying heat to the organic fabric in an inert environment to form a conductive fabric; and attaching one or more electrical terminals to the conductive fabric.

The foregoing and other embodiments can each optionally include one or more of the following features, alone or in combination.

In some implementations, applying the heat to the organic fabric includes maintaining the organic fabric in an inert environment having at least a specified temperature for at least a specified time period.

In some implementations, the specified temperature is 450 Celsius (° C.) or greater, 600° C. or greater, 750° C. or greater, or 900° C. or greater.

In some implementations, the specified time period is thirty minutes or greater, sixty minutes or greater, a hundred minutes or greater, or a hundred twenty minutes or greater.

In some implementations, obtaining the organic fabric includes knitting or weaving at least one yarn of degradable organic fiber into a sheet.

In some implementations, obtaining the organic fabric includes obtaining organic waste fabric.

In some implementations, the method includes coating the conductive fabric with a polymeric encapsulating material including at least one of Ecoflex™, Polydimethylsiloxane (PDMS), natural rubber latex (NRL), and Chitosan.

In some implementations, each of the one or more electrical terminals includes a snap connector or a conductive thread, the method including, for each of the one or more electrical terminals: connecting a first end of a flexible conductor to the electrical terminal; and connecting a second end of the flexible conductor to a wireless interface printed circuit board (PCB).

In some implementations, the textile sensor includes at least one of a pressure sensor, a proximity sensor, a touch sensor, a strain sensor, a wind sensor, a temperature sensor, a heating element, a triboelectric sensor, and an energy harvester.

In general, one innovative aspect of the subject matter described in this specification can be embodied in a method of producing a textile sensor, the method including: obtaining an organic fabric; applying a conductive solution to the organic fabric to form a conductive fabric; and attaching one or more electrical terminals to the conductive fabric.

The foregoing and other embodiments can each optionally include one or more of the following features, alone or in combination.

In some implementations, the conductive solution includes carbon powder mixed with dimethyl sulfoxide; and applying the conductive solution to the organic fabric includes dip-coating the organic fabric in the conductive solution, spraying the conductive solution onto the organic fabric, or rolling the conductive solution onto the organic fabric.

In some implementations, obtaining the organic fabric includes: knitting or weaving at least one yarn of degradable organic fiber into a sheet; or obtaining organic waste fabric.

In some implementations, the method includes coating the conductive fabric with an encapsulating material including at least one of Ecoflex™, Polydimethylsiloxane (PDMS), natural rubber latex (NRL), and Chitosan.

In some implementations, the method includes, for each of the one or more electrical terminals: connecting a first end of a flexible conductor to the electrical terminal; and connecting a second end of the flexible conductor to a wireless interface printed circuit board (PCB).

In general, one innovative aspect of the subject matter described in this specification can be embodied in a textile sensor including: a conductive fabric; an encapsulation layer including an organic elastomer coating the conductive fabric; and one or more electrical terminals connected to the conductive fabric.

The foregoing and other embodiments can each optionally include one or more of the following features, alone or in combination.

In some implementations, the conductive fabric includes a knitted or weaved sheet of degradable organic fabric that has been carbonized by applying heat to the sheet in an inert environment.

In some implementations, the conductive fabric includes a knitted or weaved sheet of degradable organic fabric that has been coated with a conductive solution including carbon.

In some implementations, the encapsulation layer includes at least one of Ecoflex™, Polydimethylsiloxane (PDMS), natural rubber latex (NRL), and Chitosan.

In some implementations, the textile sensor includes, for each of the one or more electrical terminals, a flexible conductor connected at a first end to the electrical terminal and at a second end to a wireless interface printed circuit board (PCB).

In some implementations, the textile sensor includes at least one of a pressure sensor, a proximity sensor, a touch sensor, a strain sensor, a wind sensor, a temperature sensor, a heating element, a triboelectric sensor, and an energy harvester.

According to some implementations, a method includes preparing an organic fabric by knitting or weaving a yarn made from organic fibers into a target arrangement for the textile sensor, carbonizing the organic fabric by heating the organic fabric at a specified temperature for a specified time period in an inert environment, and connecting one or more electrical terminals to one or more sides of the organic fabric.

Implementations may include one or more of the following features. In some aspects, the method includes coating the organic fabric with an encapsulating material. The encapsulating materials can include at least one of Ecoflex™, Polydimethylsiloxane (PDMS), natural rubber latex (NRL), and/or Chitosan. In some aspects, the method includes selecting the encapsulating material and/or a process for coating the organic fabric with the encapsulating material based on a type of the textile sensor.

Some aspects include selecting a particular carbonization process from a plurality of carbonization processes based on a type of the textile sensor. Each carbonization process can include a corresponding activation temperature, activation time period, ramp-up time period, and ramp-down time period.

According to some implementations, a textile sensor includes a knitted or weaved organic fabric carbonized and configured into a target arrangement for the textile sensor, an encapsulation layer that includes an organic elastomer that coats the carbonized organic fabric, and one or more electrical terminals connected to one or more sides of the target arrangement of the carbonized organic material. The carbonized fabric can have one or two terminals, depending on the type of sensor or element. The terminals are connected to the target arrangement through an attachment means such as conductive threads or button snaps

The textile sensor can be, for example, a pressure sensor, a proximity sensor, a touch sensor, a gas sensor, a chemical sensor, a strain sensor, a wind sensor, a temperature sensor, a heating element, a triboelectric sensor, and an energy harvester.

The methods in accordance with the present disclosure can include any combination of the aspects and features described herein. That is, methods in accordance with the present disclosure are not limited to the combinations of aspects and features specifically described herein, but also may include any combination of the aspects and features provided.

The details of one or more implementations of the present disclosure are set forth in the accompanying drawings and the description below. Other features and advantages of the present disclosure will be apparent from the description and drawings, and from the claims.

### BRIEF DESCRIPTION OF THE DRAWINGS

FIG. 1 depicts an example environment in which textile sensors are manufactured.

FIG. 2A depicts an example digital immersion environment in which textile sensors are used to detect motion.

FIG. 2B depicts an example sailboat that has a sailcloth with textile sensors for measuring wind velocity.

FIG. 2C depicts a diagram of textile sensors detecting airflow direction.

FIG. 3A depicts a graph of resistance versus strain for an example textile sensor.

FIG. 3B depicts a graph of resistance versus pressure for an example textile sensor.

FIG. 3C depicts a graph of change in resistance versus number of washing cycles for example textile sensors.

FIG. 3D depicts a close-up view of the graph of FIG. 3C.

FIG. 4 depicts example textile sensors.

FIG. 5A depicts an example textile sensor disconnected from a printed circuit board.

FIG. 5B depicts the example textile sensor of FIG. 5A connected to the printed circuit board.

FIG. 6 depicts a flow chart of an example process for manufacturing and deploying a textile sensor.

### DETAILED DESCRIPTION

The disclosed techniques provide methods for upcycling waste fabrics into functional textile elements through carbonization without the need for additional materials. Carbonization processes and encapsulation techniques are implemented to improve the response, durability, and washability of the carbonized textiles. The carbonized textiles can be implemented as sensors, interconnects, and heating elements. Applications include a haptic-transfer fabric, a joint-sensing wearable, and an intelligent sailcloth. The sensors can be composted, re-carbonized, and coated onto other fabrics, or repurposed into different sensors towards their end-of-life to promote a circular manufacturing process. A circular manufacturing process reduces waste and pollution by creating products with durability, reuse, remanufacturing, and recycling as key features that drive the design and material selection.

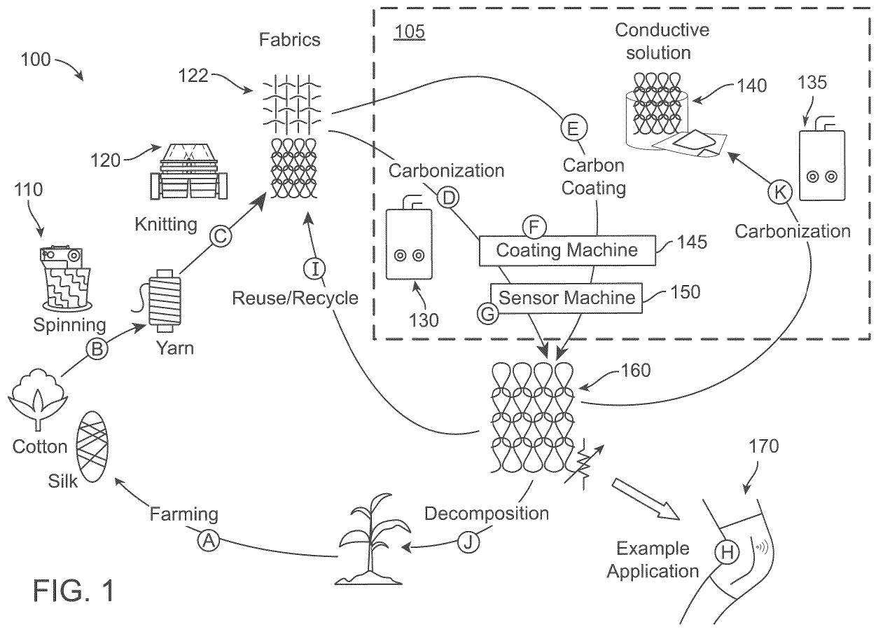

FIG. 1 depicts an example environment 100 in which textile sensors are manufactured. The example environment 100 includes a textile spinning machine 110, a knitting machine 120, a furnace 130, and a manufacturing system 105.

In stage A, organic fibers are cultivated, e.g., at a farm. An organic fiber is a fiber that is derived from living matter. The organic fibers can include, for example, cotton, silk, linen, and/or other appropriate organic fibers. In stage B, the spinning machine 110 spins the organic fibers into yarn. In stage C, the knitting machine 120 knits the yarn into knit fabric 122. In other examples, a weaving machine weaves the yarn into woven fabric 122. In some examples, the fabric 122 can be formed from fusing, embroidery, sewing, weaving, or knitting by hand or machines. The type of fabric and how the fabric is knitted or woven can depend on the type of textile sensor being produced. For example, yarn can be routed to the appropriate knitting machine or weaving machine based on the type of textile sensor being produced. The yarn can be knitted or weaved into individual sized sheets for individual sensors or into larger sheets that can be trimmed to individual sized sheets for the individual sensors.

The organic fabrics 122 can be used in some other way prior to being transported to the manufacturing system 105. For example, the organic fabrics can be used for other routine purposes, such as clothing, bedding, paper, coffee filters, tires, parachutes, and so on. When the fabrics 122 are no longer in use, the fabrics 122 may be donated or recycled, and collected for processing by the manufacturing system 105. Thus, rather than discarding these products, the organic fabrics can be reused by the manufacturing system 105 as organic waste fabric to produce textile sensors.

In some examples, the fabric 122 includes waste cotton fabric that has previously been used for other purposes. Cotton woven and knit fabrics (e.g., 100% cotton, twill weave, and weft knit) are abundant and are renewable materials derived from natural resources. Cotton is the most common organic fiber in garment manufacturing and can be found in about a third of textiles. Cotton is integrated into shirts, jeans, sheets, gloves, sweats, underwear, and towels. Cotton is used for its softness, breathability, durability, and absorbency.

The organic fabrics 122 made from organic fibers can be transported to a facility that includes the manufacturing system 105. The manufacturing system 105 includes a conductive solution 140, a coating machine 145, furnaces 130, 135, and a sensor machine 150. The manufacturing system 105 is configured to produce conductive textile fabrics with enhanced sustainability as part of the circular manufacturing cycle. The various machines and components of the manufacturing system 105 can be connected using conveyor belts or other appropriate routing material handling mechanisms for routing materials between the various machines and components.

In stage D, the furnace 130 carbonizes the fabric by heating the fabric in an inert environment according to a specified heating process for the type of textile sensor (e.g., pressure, strain, proximity, etc.) being produced and/or based on the desired conductivity for the fabric (e.g., to have an appropriate conductivity for uses as conductive, capacitive, triboelectric, or piezoresistive sensors). Carbonization is a pyrolytic or thermochemical reaction in which heat is provided in the absence of oxygen. Carbonization is a pyrolytic reaction in which many reactions take place concurrently such as dehydrogenation, condensation, hydrogen transfer and isomerization. The degree of carbonization and the residual content of foreign elements after carbonization depend on the temperature applied. For example, the carbon content of the residue may be ninety percent by weight at a temperature of 1200 Kelvin, whereas at a temperature of 1600 Kelvin, the carbon content of the residue can be more than ninety nine percent.

Carbon can be found in all organic compounds, including cellulose formed by plants in the form of linen, wood, hemp, or cotton, or carbon-containing polymers produced by animals in the form of wool, cashmere, and silk. Carbonization is a thermal decomposition process that converts cellulose or carbon-containing polymers with millions of molecules, such as H₂O, CO₂, and CO, into carbon with a distorted graphite structure under high temperature in an inert atmosphere with an absence of oxygen. Carbonization of organic materials such as wood and silk fabrics can increase their conductivity. Carbonization can convert a single material into an active element using high temperature and inert gasses without requiring any other additional material or fabrication steps.

Before carbonization, the organic fabric can be washed in deionized water (e.g., for 5 minutes) and then dried (e.g., at 60 degrees Celsius (° C.) for one hour). The organic fabric can be carbonized under a mixed atmosphere of argon-hydrogen (5% hydrogen) in a tube furnace (CM Rapid Temp 1730, Furnace Inc). The furnace includes a furnace box with an alumina tube and gas and temperature control system. In some examples, the furnace is initially heated from 25° C. to a temperature between 400° C. and 1000° C. The temperature of the furnace can be increased at a rate of, for example, 5° C. per minute or greater, 6° C. per minute or greater, 7° C. per minute or greater. The furnace can be heated, for example, to a temperature of 450° C. or greater, 600° C. or greater, 750° C. or greater, or 900° C. or greater. Heat can be applied to the organic fabric for a time duration of between zero and one hundred fifty minutes. For example, temperature can be maintained steady at a temperature of 450° C. or greater for a time duration of thirty minutes or greater, sixty minutes or greater, a hundred minutes or greater, or a hundred twenty minutes or greater.

The temperature can be reduced at a rate of, for example, 2° C. per minute or greater, 3° C. per minute or greater, 4° C. per minute or greater. The temperature of the furnace can be reduced to room temperature. The process of reducing the temperature can take between four and ten hours, depending on the maximum temperature and steady time.

The heating process for a particular type of textile sensor can be selected to give the fabric an appropriate conductivity and conductivity range for the type of textile sensor being produced. For example, touch sensors may employ carbonized fabrics having higher conductivity than those used for pressure and wind sensors. The carbonization process for each type of textile sensor can specify the temperature of the furnace 130, the time period for heating the fabric, and any adjustments to the temperature during the carbonization process, e.g., in cases in which the temperature is ramped up and/or down during the carbonization process.

In some examples in stage E, a coating machine 145 can coat the organic fabric with a conductive solution 140 to impart conductivity to the fabric. In some examples, coating the organic fabric at stage E is performed instead of carbonizing the organic fabric at stage D.

In some examples, the conductive solution 140 is made from carbon powder. The carbon powder can be obtained commercially, produced from charcoal, or produced from previously carbonized fabrics by crushing or grinding. For example, recycled carbonized cotton fabrics can be crushed into carbon powder. The carbon powder can be mixed with dimethyl sulfoxide (DMSO) as a solvent. DMSO is a byproduct of paper making. In some examples, 0.02 grams (g) of carbon powder can be mixed for every 1.0 milliliter (ml) of DMSO. The carbon powder can be stirred in a beaker (e.g., with a magnet) for a time duration (e.g., five minutes). The solution can then be sonicated to distribute the carbon particles evenly in a homogenizer. For example, the solution can be sonicated for thirty minutes at 5000 to 7000 revolutions per minute (rpm).

Before coating the organic fabric 122 with the conductive solution 140, the organic fabric 122 can be washed with deionized water (e.g., for five minutes) and dried (e.g., at 60° C. for one hour). In some examples, the organic fabric 122 is dip-coated in the conductive solution 140 (e.g., for thirty minutes) and baked (e.g., in a 60° C. oven for an hour). The dip-coating process can be repeated until a target resistance (e.g., one kiloOhm (kOhm) or greater, ten kOhm or greater, a hundred kOhm or greater) is achieved. In some examples, the conductive solution 140 is applied to the organic fabric 122 by spraying the organic fabric 122 or by rolling the conductive solution 140 onto the organic fabric 122.

In stage F, a coating machine 145 encapsulates the carbonized or conductive solution 140-coated fabric with an encapsulation material. For example, the coating machine 145 can encapsulate the carbonized fabric in a soft polymeric substrate, such as Ecoflex™, PDMS, NRL, and/or Chitosan to improve the fabric's durability and washability.

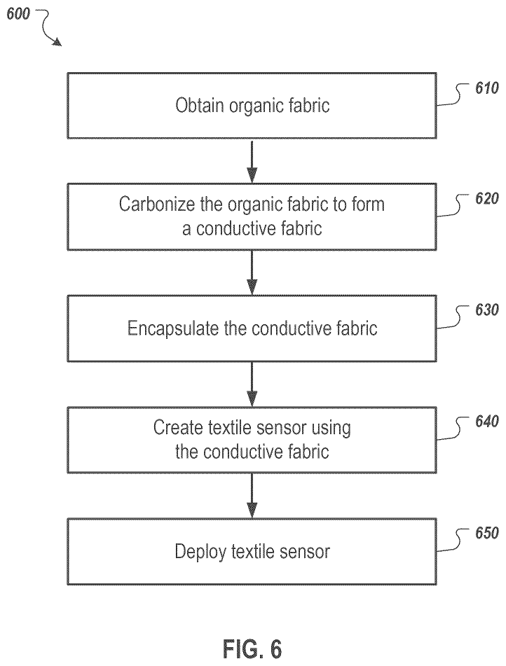

NRL and Chitosan are natural polymers and are biodegradable. Therefore, using NRL or Chitosan can enhance the fabric's degradability (e.g., biodegradability) at the end of the useful life of the fabric. Similar to the carbonization process, the encapsulation substance can be selected based on the type of textile sensor being produced. Encapsulation can significantly improve the performance, durability, and washability of the sensors. Example encapsulation processes are described below with reference to FIG. 6.

In stage G, the sensor machine 150 creates a textile sensor 160 using the encapsulated fabric. For example, the sensor machine 150 can attach conductors to appropriate sides of the fabric to serve as terminal connections to connect to an interface circuit that detects or measures a physical property based on the voltage between the terminal connections and/or the current flowing through the terminal connections. In some examples, the sensor machine 150 applies electrical terminals to the encapsulated fabric with solder paste. In some examples, the conductive fabric is connected to a flexible conductor, such as an electrical wire or conductive thread. In some examples, the conductive fabric is connected to thin multi-strand insulated wires or TPU-insulated conductive thread. In some examples, the wires or thread are attached onto the conductive fabric using electrically conductive paste (8331S, MG Chemical) and cured in an oven (e.g., at 65° C. for two hours). In some examples, insulated conductive thread can be directly sewn or stitched through the conductive fabric.

Depending on the type of sensor, a change in a physical property can change the conductivity of the fabric between the terminal connections, which changes the voltage drop between the terminal connections and/or the current flowing through the terminal connections. For example, stretching carbonized knitted fabric changes the conductivity of the fabric. This change in conductivity can be measured and used to determine the amount of strain applied to the carbonized knitted fabric.

The sensor machine 150, or another appropriate machine, can attach the created textile sensor 160 to another fabric, e.g., to a wearable or sail, or to another appropriate material with which the textile sensor 160 will be used. The sensor machine 150 can also connect the terminal connections to an interface circuit using wires or other appropriate conductors. The interface circuit is configured to detect or measure the physical property for the textile sensor.

In some examples, the interface circuit is a printed circuit board (PCB). The PCB can be a rigid or flexible circuit board. In some examples, the PCB is an ultra thin flexible PCB. In the example depicted in FIG. 1, the textile sensor 160 is attached to a knee brace 170 to measure changes in the flexing of a wearer's knee in stage H. For example, the textile sensor 160 can be a strain sensor located in front of or behind the knee to measure the strain placed on the carbonized fabric of the sensor 160 when the wearer flexes their knee.

The textile sensor 160 can be reused or recycled in stage I, decomposed in stage J, or recycled for use in conductive solution in stage K.

In stage I, the textile sensor 160, or parts of the textile sensor 160, are recycled for use in a new textile sensor. In this way, organic waste fabric can be obtained from a previously used textile sensor for use in new textile sensor. In some examples, the interface circuit and/or other electrical components (e.g., terminal connections) are removed from the fabric of the textile sensor 160 before recycling. The electrical components can then be discarded or attached to a different textile sensor. The fabric portion of the textile sensor 160 can be attached to another product (e.g., by sewing using conductive threads or using button snaps as the electrical connections). In some examples, the electrical components remain attached to the fabric when recycling. The fabric, with attached electronic components, can then be integrated into a different sensor and/or a different product.

In some examples, the textile sensor 160 includes detachable electrical components. For example, the textile sensor 160 can include a pocket formed from two pieces of fabric, with a PCB positioned in the pocket. The PCB can then be removed from the pocket when recycling the textile sensor 160. In some examples, the entire textile sensor 160 is detachable from the product (e.g., garment/knee brace 170), and the textile sensor 160 as a whole can be reused with other products, such as garments and sailcloths.

In stage J, the textile sensor 160, or parts of the textile sensor 160, are decomposed. As the textiles are organic materials and some encapsulation materials are biomaterials, these components of the textile sensor can be decomposed and turned back into the soil in stage J. Components of the textile sensor 160 that are not chemically degradable or biodegradable, such as non-degradable electrical components, can be removed before decomposition.

In stage K, the textile sensor 160 (minus non-degradable components) can be used to form a conductive solution 140 for application to another textile sensor. In some examples, the textile sensor 160 is carbonized back to carbon powder through heating and/or crushing. In some examples, the textile sensor 160 is heated by furnace 135. The furnace 135 can be the same furnace as the furnace 130 or can be a different furnace. The carbon powder output from the furnace 135 can then be used to form the conductive solution 140 that is applied to another swatch of waste fabric (e.g., in stage E) to promote and enable sustainable circular manufacturing. Thus, FIG. 1 provides three end-of-life scenarios for the textile sensor 160: recycling/reuse in stage I, decomposition in stage J, or carbonization to form carbon powder to create a new sensor in stage K.

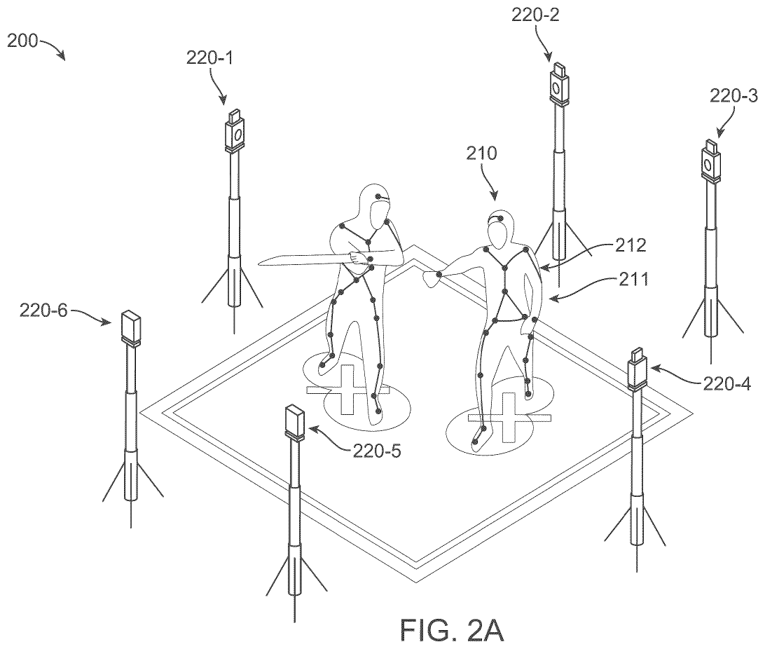

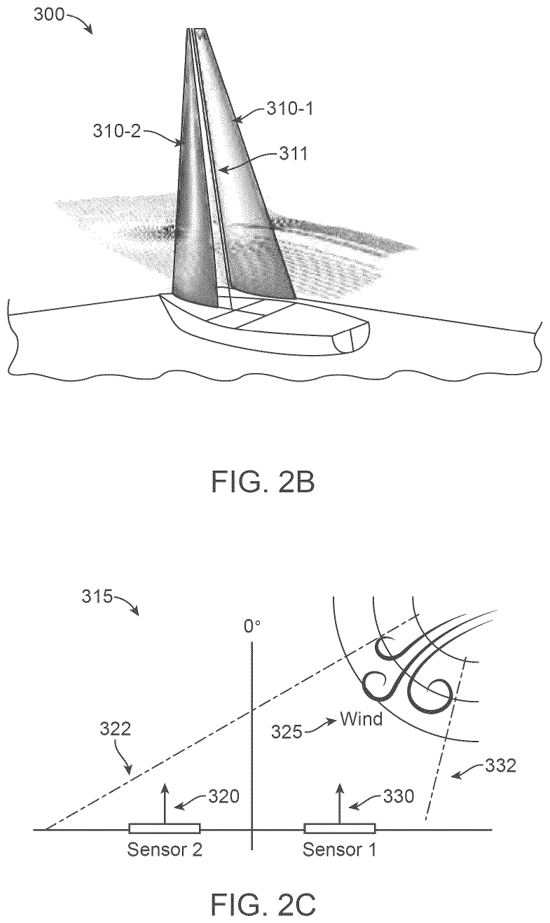

FIG. 2A depicts an example digital immersion environment 200 in which textile sensors are used to detect motion. In the digital immersion environment 200, “players” navigate a shared virtual reality (VR) using avatars of themselves. Immersive virtual environments encapsulate several advantages for digital communication, such as spatial audio, eye, and body tracking, in ways that create this bond between the body and these virtual environments. In the example of FIG. 2A, users wear body suits 210 with multiple textile sensors located on the suit 210 to measure various motions made by the users wearing the suits 210. The textile sensors 211 are connected by flexible conductors such as wires 212 that are routed from an interface circuit to the textile sensors 211 such that the interface circuit can detect or measure the various properties to support the digital immersion environment 200. Additional sensors 220, e.g., sensors 220-1 to 220-6, are located around the users to measure additional properties, such as the users' relative location. Each sensor 211 and 220 can include a wireless transmitter or transceiver that sends the measured signals to a computing system that can process the measured properties in support of the digital immersion environment 200. E-textiles can thus be implemented to perform “in-situ” body tracking, with an avatar linked to the player's joints (e.g., elbows, knees) via e-textile strain sensors integrated into the suit 210. Individual joints from the human body can be digitized and merged with a digital avatar, allowing the user to immerse themselves in the experience and control their digital counterpart seamlessly.

The disclosed textile sensors can be implemented for haptic telepresence applications. In an example, a textile sensor-actuator can include a first conductive textile swatch configured as a touch fabric sensor, and a second conductive textile swatch configured as a fabric heating element. The touch fabric sensor can be attached to a first item of clothing for wear by a first user, and the fabric heating element can be attached to a second item of clothing for wear by a second user. When the first user touches the touch fabric sensor, the touch fabric sensor activates, transmitting a signal to the fabric heating element. In response to receiving the signal, a power transistor of the fabric heating element is activated and current flows through the fabric heating element. Thus, the fabric heating element activates, providing heat to the body of the second user.

FIG. 2B depicts an example sailboat 300 that has sailcloths 310-1 and 310-2 with textile sensors 311 for measuring wind (e.g., airflow) velocity. In this example, each sailcloth 310 can include textile wind sensors 311 arranged throughout the sailcloth 310 to measure wind velocity along each portion of the sailcloth 310. A carbonized textile pressure sensor can be used to detect small forces caused by airflow. The sensor's resistance drops as wind speed increases. The measured resistance can be correlated to levels of airflow ranging from a gentle breeze to a strong gale (e.g., as measured by the Beaufort wind force scale). An interface connected to the sensors 311 can measure the wind velocity and provide the measurements to a computing system of the sailboat 300, which can adjust the sailcloths 310 based on the wind velocity measurements.

FIG. 2C depicts a diagram 315 of textile sensors detecting airflow direction. With two or more fabric pressure sensors arranged in an array, wind direction can be measured. The direction of wind can be determined by comparing the amplitude ratio between airflow force measured by the two or more fabric pressure sensors. Each fabric pressure sensor has a sensing face that is approximately planar, a normal vector to the sensing face being orthogonal to the plane of the sensing face. An incident wind direction that is parallel to the normal vector of a fabric pressure sensor will result in a higher measured force compared to a wind direction that is orthogonal to the normal vector of the fabric pressure sensor. Accordingly, a wind direction that is offset from the normal vector by a smaller angle will result in a higher measured force compared to a wind direction that is offset from the normal vector by a larger angle. Thus, the direction of the wind can be determined by calculating the amplitude ratio between the pressure sensors.

For example, referring to FIG. 2C, Sensor 1 has a normal vector 330 and Sensor 2 has a normal vector 320. A first angle between a direction 332 of incident wind 325 on Sensor 1 and the normal vector 330 is smaller than a second angle between a direction 322 of incident wind 325 on Sensor 2 and the normal vector 320. Therefore, Sensor 1 is expected to detect a stronger wind force than Sensor 2. The ratio between the force of airflow measured by Sensor 1 and the force of airflow measured by Sensor 2 can be used to estimate the direction of the wind 325.

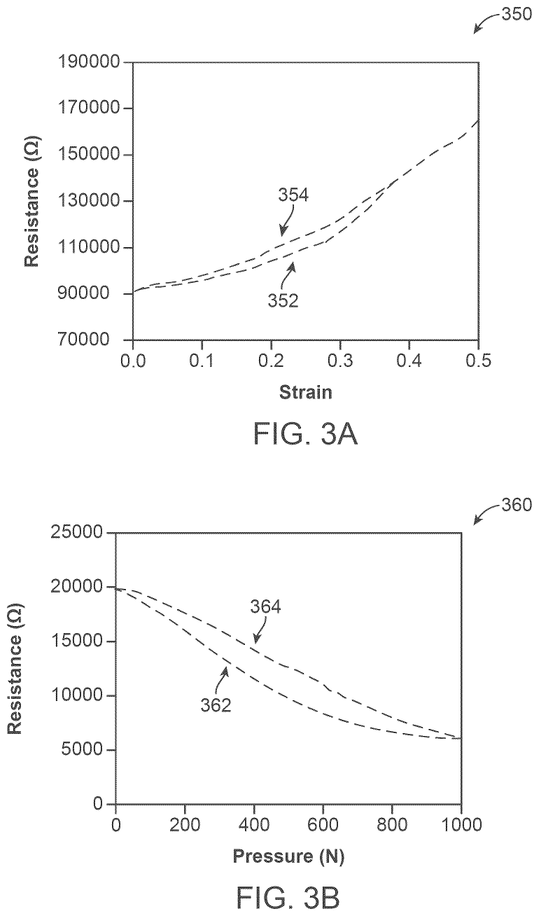

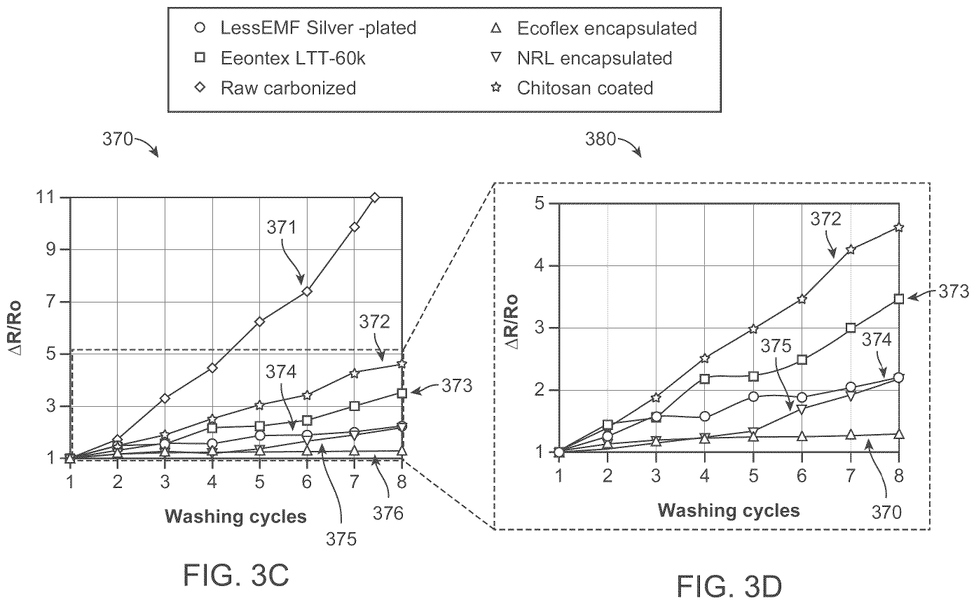

FIG. 3A depicts a graph 350 of resistance versus strain for an example textile sensor. The example textile sensor is a carbonized cotton textile strain sensor encapsulated in Ecoflex. A first trend line 354 shows resistance as strain is applied, and a second trend line 352 shows resistance as strain is removed. As shown in the graph 350, resistance of the carbonized textile sensor is directly proportional to the applied strain. This is due to the breakage in the conductive network as the sensor is being stretched, increasing the total resistance.

Encapsulation of the carbonized textile sensor suppresses hysteresis by enabling the sensor to return to its original position after strain. Thus, the carbonized textile strain sensor shows a lower hysteresis response (e.g., AR/Rdynamic=10 k/75 k or 13%) compared to similar polymerized textile sensors, which can have AR/Rdynamic of approximately 18 k/80 k or 22%), where AR is the largest gap between resistance of the trend lines 352, 354, and Rdynamic is the dynamic range of the sensor.

Encapsulation also improves the sensitivity of a carbonized textile sensor because additional compression is exerted onto the fabric while the sensor is being stretched. Thus, the carbonized textile sensor has a better sensitivity (e.g., ΔR/Ro=1.8) than similar polymerized textile sensors, which can have a ΔR/Ro of approximately 1.6), where AR is the largest gap between resistance of the trend lines 352, 354, and Ro is the initial resistance value of the sensor.

Encapsulation improves the longevity of a carbonized textile sensor by reducing fragility in response to dynamic strain. The same encapsulated carbonized knit strain sensor could manage stable electrical performance even after 100 cyclic strain cycles. In some examples, carbonized woven cotton can be used to form a strain sensor by encapsulating carbonized woven cotton fabric in a silicone rubber. As the sensor is stretched, the silicone rubber applies pressure to the woven cotton sensor and changes its resistance. However, knit sensors are more robust with a large strain and exhibit superior performance for strain sensing compared to woven sensors.

FIG. 3B depicts a graph 360 of resistance versus pressure for an example textile sensor. The example textile sensor is a carbonized cotton textile pressure sensor on a base cotton fabric. A first trend line 362 shows resistance as pressure is applied, and a second trend line 364 shows resistance as pressure is removed. As shown in the graph 360, resistance of the carbonized textile sensor is inversely proportional to the applied pressure. This is due to the squishing of the conducting network of the fabric.

FIG. 3C depicts a graph 370 of change in resistance versus number of washing cycles for example textile sensors. FIG. 3D depicts a close up view 380 of a portion of the graph 370. The graph 370 shows trend lines for raw carbonized textile 371 and for carbonized textile encapsulated in Chitosan 372, Eontex 373, LessEMF silver 374, NRL 375, and Ecoflex 376. The graphs 370, 380 show the measured resistance of each fabric swatch for each of eight washing cycles, with each washing cycle having a duration of ten minutes.

As shown in FIGS. 3C and 3D, encapsulating the carbonized fabric swatches significantly improved its washability. Ecoflex and NRL-encapsulated sensors show comparable performance, and the resistance is relatively unchanged after eight washing cycles. The Chitosan-encapsulated sensor's resistance increases every cycle, which suggests that the washing cycles gradually rip off the Chitosan protection layer. Chitosan coating can therefore be most useful as a thin, conformal protection layer for functional elements which do not need stretchable encapsulation or constant washing.

As discussed above, stretchable encapsulation improves sensitivity, washability, and durability of a knit strain sensor, and transforms non-stretchable woven fabrics that typically can be used only as pressure sensors into strain sensors. NRL can be used as a bio-based stretchable encapsulant replacement of Ecoflex, and Chitosan can be used as a water-proof thin-film coating for other types of functional elements (i.e., interconnects, capacitive, or heating elements).

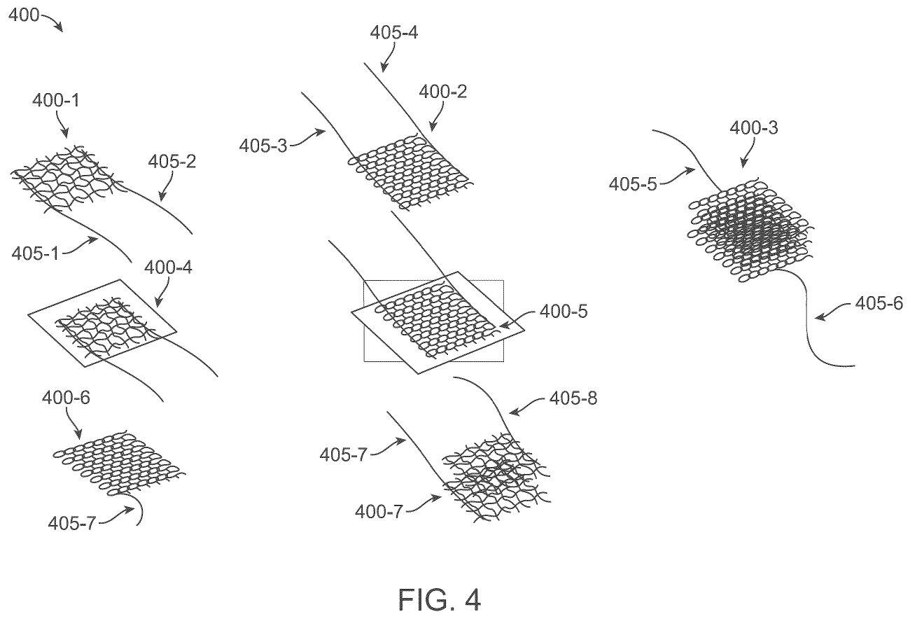

FIG. 4 depicts example textile sensors 400. The textile sensors 400 include organic fabrics that are knitted or woven, carbonized, and connected to terminal connections. The textile sensors 400 can also be encapsulated, as described herein. For example, a textile sensor 400-1 is produced by weaving an organic yarn into fabric, carbonizing the woven fabric, and attaching two electrical terminals (e.g., wires or other conductors) to a same side of the carbonized and woven fabric. This configuration can be used to produce a pressure sensor, heating element, or temperature sensor. The fabric can also be encapsulated to produce textile sensor 400-4, e.g., for a pressure sensor or a strain sensor.

In another example, a textile sensor 400-2 is produced by knitting an organic yarn into fabric, carbonizing the knitted fabric, and attaching two electrical terminals (e.g., wires or other conductors) to a same side of the carbonized and knitted fabric. This configuration can be used to produce a strain sensor, pressure sensor, heating element, or temperature sensor. The fabric can also be encapsulated to produce textile sensor 400-5, e.g., for a highly sensitive strain sensor or highly sensitive pressure sensor.

In another example, a textile sensor 400-3 is produced using multiple layers of knitted and carbonized fabrics, such as those of textile sensor 400-2. This configuration can be used to produce a highly sensitive wind sensor, highly sensitive pressure sensor, or a highly sensitive strain sensor.

In another example, a textile sensor 400-6 is produced by knitting an organic yarn into fabric, carbonizing the knitted fabric, and attaching an electrical terminal 405-7 (e.g., wire or other conductor) to a side of the carbonized and knitted fabric. This configuration can be used to produce a proximity or touch sensor. The fabric can also be encapsulated.

In another example, a textile sensor 400-7 is produced by weaving an organic yarn into fabric, carbonizing the woven fabric, and attaching two electrical terminals (e.g., wires or other conductors) to a same side of the carbonized and woven fabric. This configuration can be used to produce a highly sensitive wind sensor or a highly sensitive pressure sensor. The fabric can also be encapsulated.

Table 2 is a table of example base fabrics, structures, encapsulations, and process parameters required to fabricate various functional elements.

| | | Fabric | Temperature | Encapsulation |
|---|---|---|---|---|
| Functional Elements | Base Fabric | Structure | (Carbonization) | (Optional) |
| Interconnects | Woven Cotton | Single Layer | 900° C. | Chitosan |
| Touch/Proximity Sensor | | | | |
| Heating Element | | | | |
| Triboelectric Sensor | | | | PDMS |
| Temperature Sensor | Woven Cotton | | | — |
| Pressure Sensor | Knit Cotton | Single Layer | 750° C. | Ecoflex |
| | | Multi Layer | | PDMS |
| | | | | NRL |
| Airflow Sensor | | Multi Layer | | — |
| Strain Sensor | | Single Layer | | Ecoflex |
| | | Multi Layer | | PDMS |
| | | | | NRL |

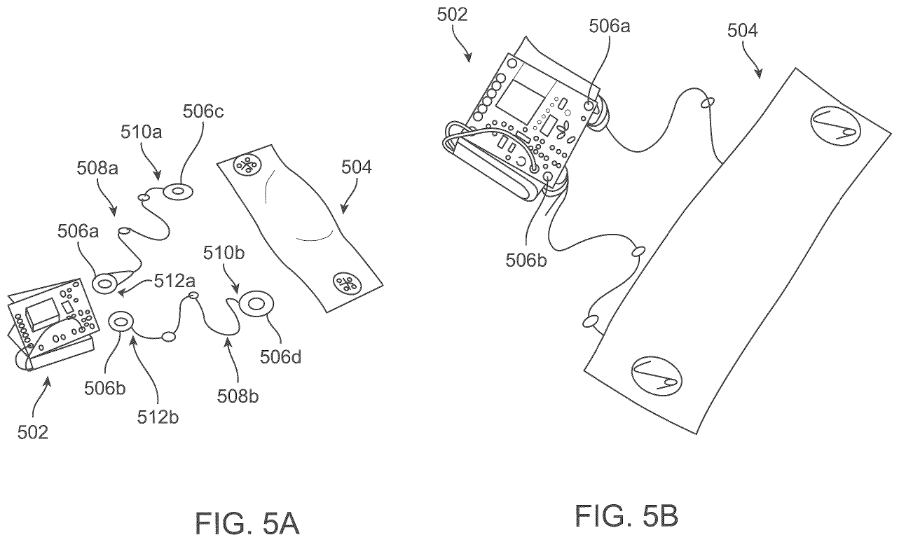

FIG. 5A depicts an example textile sensor 504 disconnected from a printed circuit board (PCB) 502. FIG. 5B depicts the example textile sensor 504 connected to the PCB 502.

The PCB 502 is a wireless interface printed circuit board. In some examples, the PCB 502 includes a BC832 Bluetooth Low-Energy (BLE) System-on-Chip (SoC) with power regulation and two resistive sensing circuits. In some examples, the PCB 502 is communicable via radiofrequency (RF), near field communication (NFC), ANT+, or other communication protocols. In some examples, the PCB 502 includes capacitive sensing components, power transistor components, voltage sensing components, or any combination thereof.

The PCB 502 includes two terminal connections 506a, 506b. The terminal connections 506a, 506b can be, for example, pads, holes, or snap connections. The PCB 502 can be electrically connected to the textile sensor 504 through flexible conductors such as conductive threads 508a, 508b. Each of the conductive threads 508a, 508b is attachable at a first end 510a, 510b to the textile sensor 504 and at a second end 512a, 512b to the terminal connections 506a, 506b. In some examples, the second ends 512a, 512b of the conductive threads 508a, 508b can be sewn or looped into the two pads of the PCB 502 for mechanical connection.

In the example of FIGS. 5A and 5B, snap connections are used for the electrical terminals on both the textile sensor 504 and the PCB 502. Specifically, male and female snaps are attached to the PCB 502 and sewn onto the textile sensor 504. The conductive threads 508a, 508b can therefore be attached and detached from both the textile sensor 504 and the PCB 502. This provides modularity such that the PCB 502 and/or the textile sensor 504 can be disassembled from the conductive threads 508a, 508b when the textile sensor 504 or the base fabric component is no longer used, needs to be washed, or needs to be recycled, upcycled, or replaced with other types of sensors.

FIG. 6 depicts a flow chart of an example process 600 for manufacturing and deploying a textile sensor. The process 600 can be performed by the manufacturing system 105 of FIG. 1 or another appropriate system.

The parameters of, and operations performed in, the manufacturing process can be selected and/or configured based on the type of textile sensor being produced. For example, knitting can be used for some types of sensors, while weaving is used for other types of sensors. In addition, the carbonization processes and encapsulation materials can be selected based on the type of textile sensor being produced. For example, the ramp-up and ramp-down time, steady time, and activation temperature of the carbonization process can be selected based on the type of textile sensor and/or organic fabric being used to result in an appropriate conductivity for the textile sensor. In addition, the encapsulation material and/or process can be selected based on the textile sensor being produced, e.g., based on the desired sensitivity of the sensor, the desired durability of the sensor, and/or the desired washability of the sensor.

An organic fabric is obtained (610). The organic fabric can be made from, for example, cotton, silk, linen, or another appropriate organic fiber. In some examples, obtaining the organic fabric includes preparing the organic fabric. The preparation of the organic fabric can include spinning the fiber into yarn and knitting or weaving the yarn into a fabric sheet having an appropriate shape for the textile sensor. The sheet can have a shape of, for example, a polygon, a non-polygon, a quadrilateral, a rectangle, a square, a circle, a triangle, or any combination thereof.

The organic fabric is carbonized to form a conductive fabric (620). The organic fabric can be carbonized by applying heat to the organic fabric in a furnace with inert gas. Alternatively, the organic fabric can be coated with a conductive solution made from carbon powder (e.g., from carbonized waste organic fabrics) mixed with a solvent.

As described above, the carbonization process can be selected based on and/or adapted to the type of textile sensor being produced. The carbonization process for a particular type of textile sensor can include an activation temperature and steady time period at which the fabric is heated at the activation temperature, a ramp-up time period from an initial temperature (e.g., ambient temperature) to the activation temperature, and a ramp-down time period from the activation temperature to a final temperature (e.g., ambient temperature).

The conductive fabric is encapsulated (630). This is an optional operation in the process 600 depending on the desired durability and sensitivity of the textile sensor being produced. A conductive fabric can be encapsulated by coating the conductive fabric with, for example, Ecoflex™, PDMS, NRL, or Chitosan. Other organic or inorganic elastomers or other appropriate encapsulation materials can also be used.

The textile sensor is created using the conductive and optionally encapsulated fabric (640). For example, electrical terminals can be connected to appropriate side(s) of the conductive fabric. Textile sensors can be connected using thin multi-strand insulated wires (e.g., 34 AWG) or TPU-insulated conductive thread (e.g., 117/17 dtex silver-coated nylon). These electrodes can be attached to the carbonized fabric using electrically conductive paste (e.g., 8331S) cured in an oven at 65° C. for around two hours. Another approach is to directly sew or stitch the insulated conductive thread (e.g., 117/17 dtex silver-coated nylon) through the knitted or woven sensors.

The created textile sensor is deployed (650). For example, the textile sensor can be attached to a bodysuit or sail and the electrical terminal(s) can be connected to an interface circuit.

The interface circuit can include a wireless transmitter or transceiver and can be mounted on a printed circuit board (PCB) with two pads or holes as two terminal connections to the textile sensors. The other two ends of the conductive threads connected to a sensor can be sewn/looped into the pads for mechanical connection. Another approach is a mechanical connection through button snaps. Male and female snaps can be attached or sewn into both the sensor and the PCB pad for mechanical connection on a carrier fabric. The interface circuit can be unplugged or disassembled when the fabric sensor component is no longer used, needs to be washed, or needs to be recycled or replaced with other types of sensors.

To support circular manufacturing, bulk organic fabrics (e.g., cotton, silk, linen) are carbonized into conductive or piezoresistive fabrics and then cut/processed in different ways, as described above, to develop various interconnects and sensors. After their usage, the fabrics can be recycled by further carbonizing and crushing into carbon powder. The carbon powder can then be mixed with a solvent to make conductive or piezoresistive ink and then coated into other organic fabrics to make various interconnects or sensors. These fabrics can be collected in bulk at their end-of-life, and the entire circular process can be repeated.

Example manufacturing processes for particular types of textile sensors are provided below. Proximity sensors and touch sensors can be produced by carbonizing knit or woven fabric in a furnace with a high activation temperature (e.g., 900° C.) to make the fabric highly conductive. One terminal can then be attached to the fabric for self-capacitive sensing. The touch and proximity sensing rely on the capacitance change between a human body as a virtual ground and a floating electrode. An MPR121 chip (NXP Semiconductor) can be used to read the capacitance by measuring the voltage given by charging each electrode for a specified time and current. As a user's hand approaches the carbonized electrode, some of the charged current is coupled to the user's body, reducing the voltage output from the steady value. When the user physically touches the electrode, a significant voltage drop can be observed, and touch events can be detected with simple thresholding.

Interconnects can be developed by leveraging conductive woven fabric carbonized at a temperature of 900° C. or higher. For example, an interconnect connected to a power supply (3.3 V) and a resistor (1 kOhm) from a carbonized weave in a base cotton fabric can be implemented to illuminate a light-emitting diode.

Strain sensors can be produced using both carbonized/coated knit or woven fabric in medium to high resistance regions (kOhm to MOhm). For carbonization, an appropriate activation temperature for this range of resistance is around 750° C. Two terminal connections can be established at two ends of the fabric sensor. For knit fabrics, stretching in the course direction gives a more sensitive response due to its more elastic property based on the knit loop structure. Based on this observation, the knit fabric strain sensor is cut in the lengthwise course direction. Change in the resistance occurs due to both knit loop structural change that influences the conductive pathways and intrinsic piezoresistive response of the coated or carbonized fabrics. The coated knit fabric can be used as a strain sensor as is or encapsulated with Ecoflex™, PDMS, NRL, or Chitosan to improve its mechanical stability, sensitivity, and washability. The encapsulation method can be important for carbonized knit fabric since it prevents the fabric from being fragile. Woven fabric can also be used as a strain sensor by encapsulating it in an elastomer (e.g., Ecoflex™, PDMS, or NRL). As the encapsulated woven fabric is stretched, due to the Poisson ratio, a transversal load or pressure toward the fabric induces resistance change.

Pressure and airflow sensors can be produced using carbonized or coated knit or woven fabric in medium to high resistance regions (kOhm to MOhm). For carbonization, an appropriate carbonization temperature for this resistance range is around 750° C. Two layers of fabric can be stacked together with interconnect terminals at each opposite end of the fabrics. Due to its large deformability, a thicker fabric such as double-knit interlock fabric can be used as a single layer for pressure sensing. The conductive pathway affected by the fabric structure's compressive structural change defines the pressure sensor's output. Light-weight fabric shrunk by carbonization results in a more sensitive response to pressure, making it useful for detecting subtle air/wind flow.

Heating elements and fire/temperature sensors can be formed from carbonized fabric. The temperature coefficient of conducting materials enables carbonized or coated fabric to act as a temperature sensor to detect the presence of a fire or cold air. The materials can also act as a heater through Joule or resistive heating mechanisms. As a heating element, a low resistance regime of 0-50 Ohm (e.g., carbonization temperature of 900° C.) can be used for lower voltage and power operation. For both sensing and heating elements, a two-terminal connection can be established at both ends of the carbonized or coated fabric.

Highly conductive carbonized fabric (e.g., carbonization temperature of 900° C.) can also be used as triboelectric sensors and energy harvesters when encapsulated in a high electron affinity material (e.g., PDMS). The conductive fabric, in this case, acts as a single conductive electrode with one electrical wiring attachment for electron transfer, while the encapsulation layer acts as the negative triboelectric material. When an electropositive material such as human skin or an acrylic plate comes in contact or releases from each other, a charge transfer occurs, and electric potential is created as the two surfaces begin to separate.

Example encapsulation processes using different encapsulation materials follow. Bottom translucent Ecoflex™ elastomer layers can be prepared by mixing Ecoflex™ kit (00-50, Smooth-On) in 1A:1B ratio. The mixture can then be poured onto a Petri dish with a thickness of 500 μm-1 mm and left in a vacuum chamber for around 15 minutes to remove the air bubbles. The bottom layer can then be half-cured at room temperature for around an hour before applying the textile sensor with its two-terminals on top of the sticky bottom layer. The setup is then left to fully cure for two hours. Top Ecoflex™ 00-50 composite can then be poured at 500 μm-1 mm thickness, degassed to remove the air bubbles, and left to cure at room temperature for around three hours to complete the encapsulation process. The sample is then peeled off from the Petri dish as a free-standing device or for further treatment onto a fabric.

Bottom transparent PDMS elastomer layers can be prepared by mixing silicone kit PDMS (e.g., Sylgard™ 184) in a 10:1 base and curing agent ratio. The mixture can then be poured onto a Petri dish with a thickness of 500 μm-1 mm and left in a vacuum chamber for around 15 minutes to remove the air bubbles. The bottom layer can then be half-cured at 65° C. for an around an hour in an oven before applying the textile sensor with its two terminals on top of the sticky bottom layer. The setup is then left to fully-cure at 65° C. in an oven for around an hour. The top PDMS mixture is then poured at 500 μm-1 mm thickness, degassed to remove the air bubbles, and left to cure at 65° C. in an oven for around two hours to complete the encapsulation process. The sample is then peeled off from the Petri dish as a free-standing device or for further treatment onto a fabric.

Prepared fabric sensors can be coated with NRL by applying the liquid latex on the surface of the fabric sensors with a brush. This process can be repeated every two hours thrice on both fabric sensor surfaces. The sample can then be left to cure in a room-temperature environment for around a day before peeling it off from the Petri dish for a free-standing device or further treatment onto a fabric.

For high durability applications that require frequent dynamic stretching and washing, Ecoflex and PDMS encapsulation can be used, due to their high stretchability and waterproofing characteristics. Ecoflex™ is a biodegradable compostable plastic biopolymer. For Ecoflex™ and PDMS encapsulated samples, the encapsulated samples can be integrated onto a carrier fabric by using a sticking layer made out of the same material (Ecoflex™ or PDMS) on the fabric's surface and the sample. After fusing the sample onto the fabric with the sticking layer in between, the complete fabric sample is then cured at room temperature for around three hours (for Ecoflex™) or heated in a 65° C. oven for around two hours (PDMS). For carbonized or coated fabric sensor samples directly encapsulated on top of a carrier fabric (woven or knitted), Ecoflex™ or PDMS can be first coated onto the carrier fabric on a Petri dish to create an interfacial layer with 500 μm-1 mm thickness. The sample can then be dip-coated into Ecoflex™ or PDMS composite and applied onto the treated fabric surface before curing it to complete the integration process.

A Chitosan solution can be prepared by diluting acetic acid into deionized water at 2% volume. Chitosan is a linear polysaccharide that can be produced by deacetylation of chitin, Medium molecular weight deacetylated Chitosan can be added to the acetic acid solution at a 1 wt % concentration and is continuously stirred for around one hour on a hotplate heated to 60° C. Glycerol can then be added to the solution as a plasticizer, with a weight ratio of about 0.33:1 or about 0.4:1 glycerol:Chitosan. The solution can be stirred at 60° C. for an around thirty minutes. The solution can then be left to cool at room temperature. After that, the prepared textile sensor is dip-coated into the solution for around five minutes and then hung until dry for around 24 hours.

The use of waste cotton fabric reduces its environmental footprint by providing a way of reusing one of the most common materials in everyday textiles and garments. The carbonization process allows us to transform cotton fabric into various e-textile devices without any additional material or complex pre- and post-processing. The carbonization method can also be implemented with other types of organic fabric such as silk, linen, bamboo, and hemp fabrics.

As described above, sensitivity, durability, and washability of textile sensors can be improved by encapsulating the textile sensors in silicone rubber (Ecoflex™/PDMS) and NRL, or Chitosan. The sensors can be reused many times and withstand daily wear and maintenance. Ecoflex™, PDMS, and NRL can be used for washable deformation sensors that need elastomeric protection from dynamic strain or pressure. In contrast, Chitosan provides a water-proof conformable layer for other types of active elements that require thin surface insulation or protection and do not typically experience large stress or do not need to be washed frequently such as interconnects, touch/proximity, temperature sensors, and heating elements. The multifunctional carbonized textile can also be recycled or repurposed into various kinds of sensors depending on the needs and applications. For example, after carbonizing a large swatch of cotton fabric for touch/proximity capacitive sensing, the fabric can also be cut in various formats and optionally encapsulated to make other sensors, such as piezoresistive pressure and strain or triboelectric sensors. Dip-coating can also be implemented with the disclosed carbonization methods to enable remanufacturing. After their usage, non-encapsulated carbonized sensors can be recycled by simply crushing them into carbon powder. For Ecoflex™ or PDMS-encapsulated sensors, the encapsulation can be peeled away before crushing the carbonized fabrics. Chitosan or NRL-encapsulated sensors can be re-carbonized in the furnace without the need of encapsulant removal and then crushed to form carbon powder. This carbon powder can then be mixed with a solvent to make functional ink or dye. The functional ink or dye can then be homogenized and coated into other organic fabrics to create new textile sensors. Textile ink or dye can be applied to a product such as a garment, forming a conductive trace while integrating with the design of the product.

Towards their end-of-life, the sensors and their substrates can be re-carbonized into carbon powder, recoated onto other organic fabrics, repurposed into different types of sensors, or decomposed into the environment to enable a closed-loop and circular system.

While this specification contains many specific implementation details, these should not be construed as limitations on the scope of any invention or of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a sub combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In certain implementations, multitasking and parallel processing may be advantageous.

What is claimed is:

1. A method of producing a textile sensor, the method comprising:
obtaining an organic fabric;
carbonizing the organic fabric by applying heat to the organic fabric in an inert environment to form a conductive fabric; and
attaching one or more electrical terminals to the conductive fabric.

2. The method of claim 1, wherein applying the heat to the organic fabric comprises maintaining the organic fabric in an inert environment having at least a specified temperature for at least a specified time period.

3. The method of claim 2, wherein the specified temperature is 450 Celsius (° C.) or greater, 600° C. or greater, 750° C. or greater, or 900° C. or greater.

4. The method of claim 2, wherein the specified time period is thirty minutes or greater, sixty minutes or greater, a hundred minutes or greater, or a hundred twenty minutes or greater.

5. The method of claim 1, wherein obtaining the organic fabric comprises knitting or weaving at least one yarn of degradable organic fiber into a sheet.

6. The method of claim 1, wherein obtaining the organic fabric comprises obtaining organic waste fabric.

7. The method of claim 1, comprising coating the conductive fabric with a polymeric encapsulating material comprising at least one of Ecoflex™, Poly dim ethyl siloxane (PDMS), natural rubber latex (NRL), and Chitosan.

8. The method of claim 1, wherein each of the one or more electrical terminals comprises a snap connector or a conductive thread, the method comprising, for each of the one or more electrical terminals:
connecting a first end of a flexible conductor to the electrical terminal; and
connecting a second end of the flexible conductor to a wireless interface printed circuit board (PCB).

9. The method of claim 1, wherein the textile sensor comprises at least one of a pressure sensor, a proximity sensor, a touch sensor, a strain sensor, a wind sensor, a temperature sensor, a heating element, a triboelectric sensor, and an energy harvester.

10. A method of producing a textile sensor, the method comprising:
obtaining an organic fabric;
applying a conductive solution to the organic fabric to form a conductive fabric; and
attaching one or more electrical terminals to the conductive fabric.

11. The method of claim 10, wherein:
the conductive solution includes carbon powder mixed with dimethyl sulfoxide; and
applying the conductive solution to the organic fabric comprises dip-coating the organic fabric in the conductive solution, spraying the conductive solution onto the organic fabric, or rolling the conductive solution onto the organic fabric.

12. The method of claim 10, wherein obtaining the organic fabric comprises:
knitting or weaving at least one yarn of degradable organic fiber into a sheet; or
obtaining organic waste fabric.

13. The method of claim 10, comprising coating the conductive fabric with an encapsulating material comprising at least one of Ecoflex™, Polydimethylsiloxane (PDMS), natural rubber latex (NRL), and Chitosan.

14. The method of claim 10, comprising, for each of the one or more electrical terminals:
connecting a first end of a flexible conductor to the electrical terminal; and
connecting a second end of the flexible conductor to a wireless interface printed circuit board (PCB).

15. A textile sensor comprising:
a conductive fabric;
an encapsulation layer comprising an organic elastomer coating the conductive fabric; and
one or more electrical terminals connected to the conductive fabric.

16. The textile sensor of claim 15, wherein the conductive fabric comprises a knitted or weaved sheet of degradable organic fabric that has been carbonized by applying heat to the sheet in an inert environment.

17. The textile sensor of claim 15, wherein the conductive fabric comprises a knitted or weaved sheet of degradable organic fabric that has been coated with a conductive solution including carbon.

18. The textile sensor of claim 15, wherein the encapsulation layer comprises at least one of Ecoflex™, Polydimethylsiloxane (PDMS), natural rubber latex (NRL), and Chitosan.

19. The textile sensor of claim 15, comprising, for each of the one or more electrical terminals, a flexible conductor connected at a first end to the electrical terminal and at a second end to a wireless interface printed circuit board (PCB).

20. The textile sensor of claim 15, wherein the textile sensor comprises at least one of a pressure sensor, a proximity sensor, a touch sensor, a strain sensor, a wind sensor, a temperature sensor, a heating element, a triboelectric sensor, and an energy harvester.
